(19) United States
(12) Patent Application Publication
(10) Pub. No.: US 2008/0200029 A1
(43) Pub. Date: Aug. 21, 2008

(54) Method of fabricating microstructures

(75) Inventors: Joontae Song, Suwon-si (KR); Hyunsuk Hwang, Suwon-si (KR)

Correspondence Address: NEEDLE & ROSENBERG, P.C., SUITE 1000, 999 PEACHTREE STREET, ATLANTA, GA, 30309-3915, US

(73) Assignee: SUNGKYUNKWAN UNIVERSITY, Suwon-si (KR)

(21) Appl. No.: 12/001,330

(22) Filed: Dec. 10, 2007

(30) Foreign Application Priority Data
Feb. 5, 2007 (KR) 10-2007-0011531

(51) Int. Cl. H01L 21/44; H01L 21/311

(52) U.S. Cl. 438/673; 438/703; 257/E21.249; 257/E21.476

(57) ABSTRACT

Provided is a method of fabricating a microstructure, and more specifically, a method of fabricating a structure of a Micro Electro Mechanical System (MEMS), which includes the step of applying and patterning a material for the sacrificial layer on a silicon substrate, and forming a post with the same material as the sacrificial layer material, so that a stiction problem can be prevented in advance at the time of fabricating the microstructure, only one process needs to be added to simplify fabrication of a post, and the sacrificial layer can be formed in a desired shape because a photoresist is used as the sacrificial layer material.

### CROSS-REFERENCE TO RELATED APPLICATION

This application claims the benefit of Korean Patent Application No. 2007-0011531, filed Feb. 5, 2007, the disclosure of which is hereby incorporated herein by reference in its entirety.

### BACKGROUND OF THE INVENTION

1. Field of the Invention

The present invention relates to a method of fabricating a microstructure, and more specifically, to a method of fabricating a structure of a Micro Electro Mechanical System (MEMS) by rapidly removing a sacrificial layer and preventing a stiction problem to enhance a process and improve the yield.

2. Description of the Prior Art

In general, a MEMS structure, which is also referred to as a microstructure, is fabricated by a wet etching process for releasing a portion of the microstructure from a substrate. Such a wet etching process causes a suspended microstructure having a space or a gap and at least one post attached to the substrate to be generated between the substrate and the released portion of the microstructure.

A shape of the suspended microstructure having the released portion may be a beam or plate which has upper and lower surfaces suspended substantially in parallel with a surface of the substrate. Examples of an apparatus having such a suspended microstructure include accelerometers, pressure sensors, flow sensors, transducers, micro-actuators, and so forth.

Meanwhile, the release etching method includes a method of generating a cavity within a substrate (bulk microprocessing) and a method of removing a sacrificial layer and a middle portion of the microstructure (surface microprocessing). In these two etching methods, the released portion of the microstructure is often permanently stuck to the substrate or a structure adjacent to the substrate in cleaning and drying steps after etching.

To detail this, in a case of a surface microprocessing technique for generating the released portion of the microstructure, a sacrificial layer is typically removed by a wet etching process. At this time, the substrate is exposed to a chemical etching solution for resolving the sacrificial layer only without affecting a material used for forming the microstructure. The substrate is then cleaned by a cleaning solution, and when such a cleaning solution is removed, a surface tension of the solution has an effect on the released portion of the suspended microstructure, so that the released portion of the microstructure sinks to cause a lower surface of the released portion to be stuck to the substrate or another structure adjacent to the substrate. This phenomenon is called stiction.

The stiction phenomenon causes the sensitivity of a sensor to be degraded, and before an element is fabricated the problem may have become severe, which may be a factor in reduced yield of a micro fabrication process.

To prevent such a stiction phenomenon, a process is carried out in a sequence in which holes are formed in a structural layer and a sacrificial layer for fabricating a proposed post and then filled with a polymer as a material for the post, so that at least five extra processes for fabricating the post must be disadvantageously added.

In addition, a method of using a photoresist as a material for the sacrificial layer and parylene as the post material forms the structure layer and post using the same material to reduce the number of processes. However, the final suspended structure has a post shape, which thus limits the fields to which a microstructure may be applied.

In addition, a method of using a photoresist as the sacrificial layer material and silicon (Si) as the post material, which is a bulk microprocessing technique, differs from a surface microprocessing technique, and has problems related to small size.

### SUMMARY OF THE INVENTION

An object of the present invention is to provide a method of fabricating a post by forming a sacrificial layer and a post with the same material and adding only one process for forming the post at the time of fabricating a microstructure.

Another object of the present invention is to provide a method of fabricating a sacrificial layer in a desired shape by using a photoresist as a material of the sacrificial layer.

An aspect of the present invention provides a scribing method of fabricating a microstructure using a sacrificial layer, the method including the step of applying and patterning a material for the sacrificial layer on a silicon substrate, and forming a post with the same material as the sacrificial layer material.

Another aspect of the present invention provides a method of fabricating a suspended microstructure, the method including the steps of: depositing a sacrificial layer on a silicon substrate; irradiating ultraviolet (UV) light on the sacrificial layer to form a temporary post depositing an aluminum structural layer on the sacrificial layer; removing the sacrificial layer by wet etching; and removing the temporary post by dry etching.

Yet another aspect of the present invention provides a method of fabricating a microstructure, the method including the steps of: preparing a silicon substrate; depositing, on the silicon substrate, a sacrificial layer which can be removed by wet etching; exposing the sacrificial layer to directly form a post within the sacrificial layer; depositing an aluminum structural layer on the sacrificial layer using a metal mask; and removing the sacrificial layer and the post to form a structural layer for generating at least one microstructure on the entire surface of the resultant structure.

### BRIEF DESCRIPTION OF THE DRAWINGS

The above and other objects, features and advantages of the present invention will be more apparent from the following detailed description taken in conjunction with the accompanying drawings, in which:

FIG. 1 is a process flow diagram illustrating a process of fabricating a microcantilever according to an exemplary embodiment of the present invention;

FIG. 2 is a process flow diagram illustrating a process of fabricating a large suspended structure according to an exemplary embodiment of the present invention; and

FIGS. 3A, 3B, 3C, and 3D are photographs of the suspended structures fabricated according to an exemplary embodiment of the present invention.

### DETAILED DESCRIPTION OF EXEMPLARY EMBODIMENTS

First, an operational procedure of the present invention will be described in detail with reference to the accompanying drawings.

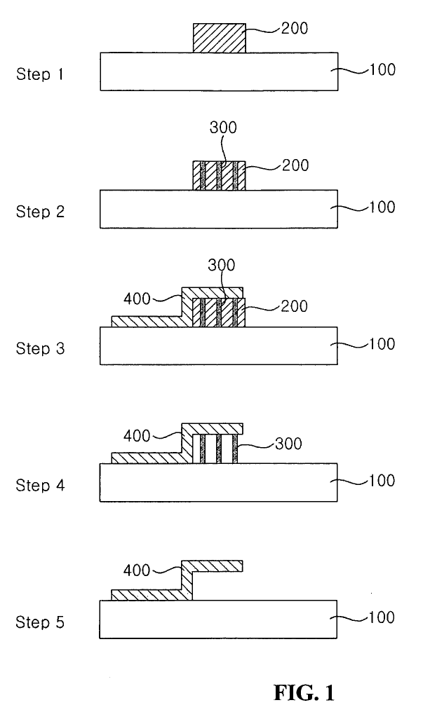

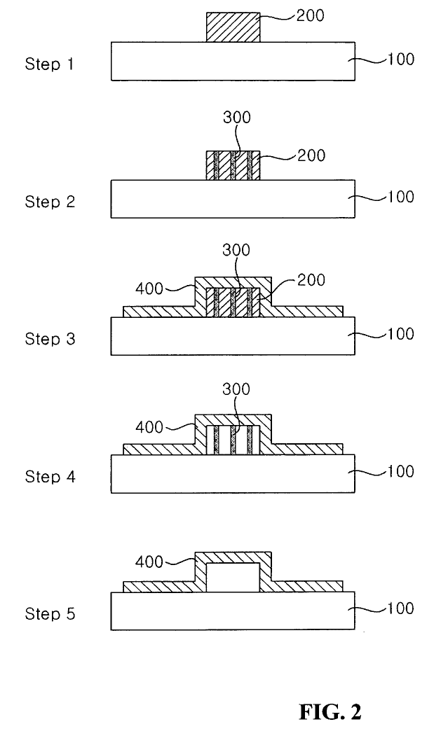

FIG. 1 is a process flow diagram illustrating a process of fabricating a microcantilever according to an exemplary embodiment of the present invention, and FIG. 2 is a process flow diagram illustrating a process of fabricating a large suspended structure according to an exemplary embodiment of the present invention. As shown in FIGS. 1 and 2, a substrate 100 having a predetermined shape is formed of a suitable material such as silicon. A photoresist is applied on the silicon substrate 100 as a sacrificial layer 200, which is then patterned (step 1).

The photoresist is used as the sacrificial layer material in the present invention, and is removed by a developing solution instead of a strong acid compared to a typical material for the sacrificial layer as shown in Table 1, so that it can be advantageously removed without affecting other layers, such as a structural layer.

TABLE 1

| | Application | | |
|---|---|---|---|
| Sacrificial layer | (deposition) | | Removal |
| material | process) | Shape fabrication | material |
| SiO₂, p-Si, | LPCVD, | Coating protective | Strong acid |
| Metal | evaporator | layer and fabricating | |
| | | shape, fabricating | |
| | | shape of sacrificial layer | |
| Photoresist | Spin coating | Exposure and development | Developing |
| | | | solution |

After the sacrificial layer 200 is patterned, a post 300 is formed of a photoresist which is the same material as the sacrificial layer 200 (step 2).

That is, a post pattern mask is exposed to the sacrificial layer pattern, and then the post 300 is directly formed within the sacrificial layer 200.

An aluminum structural layer 400 is deposited using an evaporator (not shown) (step 3). At this time, a metal mask is used for deposition in the present invention, so that a separate mask and a separate etching process are not required for patterning.

When the aluminum structural layer 400 is completely deposited, the sacrificial layer 200 is removed by wet etching using a developing solution (step 4). At this time, the post 300 is not exposed so that it is not removed by the developing solution.

The post 300 is then removed by dry etching using an oxygen plasma asher to leave a microcantilever as an aluminum structural layer or a large suspended structure (step 5).

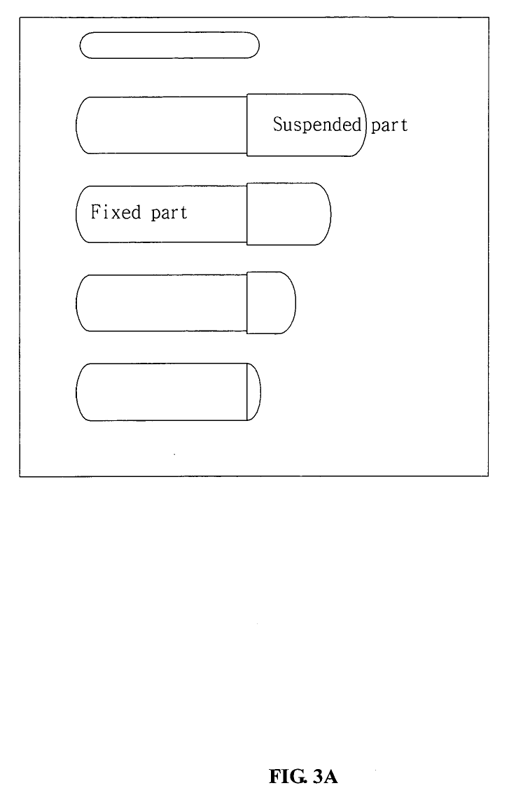

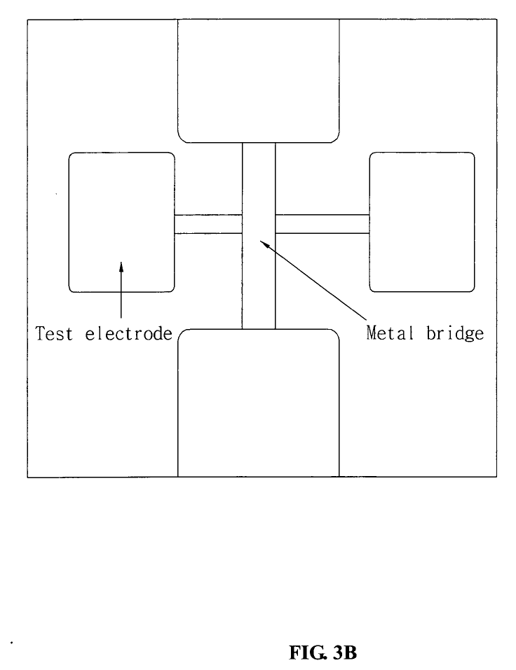

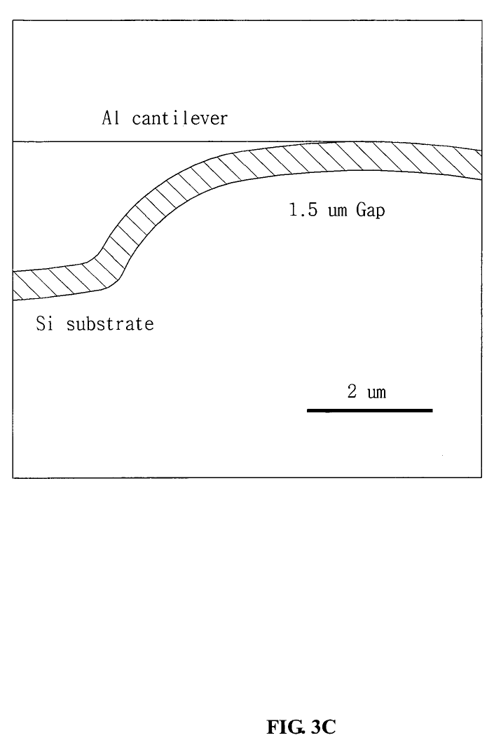

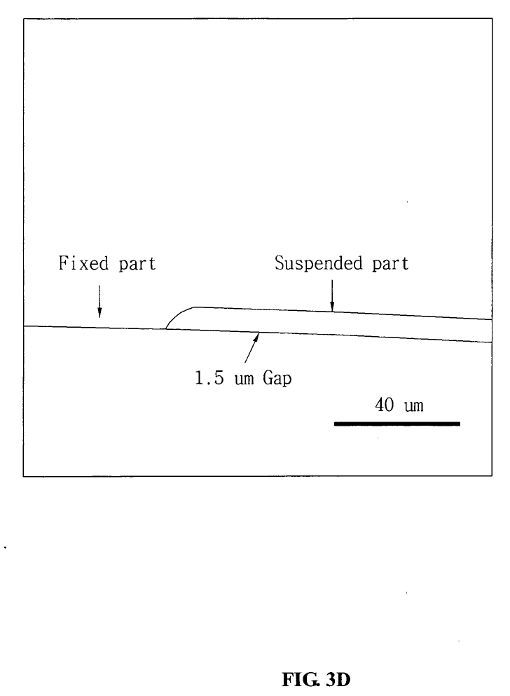

FIGS. 3A, 3B, 3C, and 3D are photographs of the suspended structures fabricated according to an exemplary embodiment of the present invention.

When the suspended parts shown in FIGS. 3A and 3B are viewed using a scanning electron microscope, it can be seen whether the structures are suspended as shown in FIGS. 3C and 3D.

According to a method of fabricating a microstructure of the present invention, a stiction problem can be prevented in advance at the time of fabricating the microstructure, only one process needs to be added to simplify fabrication of a post and a photoresist is used as a sacrificial layer material, so that the sacrificial layer having a desired shape can be easily fabricated.

While this invention has been described with reference to exemplary embodiments thereof, it will be clear to those of ordinary skill in the art to which the present invention pertains that various modifications may be made to the described embodiments without departing from the spirit and scope of the present invention as defined in the appended claims and their equivalents.

What is claimed is:

1. A method of fabricating a microstructure using a sacrificial layer, comprising the step of:
applying and patterning a material for the sacrificial layer on a silicon substrate, and forming a post with the same material as the sacrificial layer material.

2. The method according to claim 1, wherein the sacrificial layer and post materials are a photoresist.

3. The method according to claim 1, further comprising the step of:
directly forming a post within the sacrificial layer after exposing a post pattern mask to the patterned sacrificial layer.

4. The method according to claim 1, further comprising the step of:
removing the sacrificial layer by wet etching using a developing solution.

5. The method according to claim 1, further comprising the step of:
removing the post by dry etching using an oxygen plasma asher.

6. A method of fabricating a suspended microstructure, comprising the steps of:
depositing a sacrificial layer on a silicon substrate;
irradiating ultraviolet (UV) light on the sacrificial layer to form a temporary post;
depositing an aluminum structural layer on the sacrificial layer;
removing the sacrificial layer by wet etching; and
removing the temporary post by dry etching.

7. The method according to claim 6, wherein the sacrificial layer and the temporary post are formed of a photoresist.

8. The method according to claim 6, wherein the sacrificial layer is removed by wet etching using a developing solution.

9. The method according to claim 6, wherein the temporary post is removed by dry etching using an oxygen plasma asher.

10. A method of fabricating a microstructure, comprising the steps of:
preparing a silicon substrate;
depositing, on the silicon substrate, a sacrificial layer which can be removed by wet etching;
exposing the sacrificial layer to directly form a post within the sacrificial layer,
depositing an aluminum structural layer on the sacrificial layer using a metal mask; and
removing the sacrificial layer and the post to form a structural layer for generating at least one microstructure on the entire surface of the resultant structure.

11. The method according to claim 10, wherein the sacrificial layer and the post are formed of a photoresist.

12. The method according to claim 10, wherein a developing solution is used when the sacrificial layer is removed.

13. The method according to claim 10, wherein an oxygen plasma asher is used when the post is removed.
